(19) United States
(12) Patent Application Publication
(10) Pub. No.: US 2023/0314955 A1
(43) Pub. Date: Oct. 5, 2023

(54) PHOTORESIST STRIPPER AND METHOD OF TREATING SUBSTRATE USING SAME

(71) Applicant: TOKYO OHKA KOGYO CO., LTD., Kawasaki-shi (JP)

(72) Inventors: YaChien Chuang, Kawasaki-shi (JP); Yugeng Wu, Kawasaki-shi (JP)

(21) Appl. No.: 18/190,803

(22) Filed: Mar. 27, 2023

(30) Foreign Application Priority Data
Mar. 29, 2022 (TW) 111111862

(51) Int. Cl. G03F 7/42; C11D 1/40; G03F 7/038

(52) U.S. Cl. CPC G03F 7/425; C11D 1/40; G03F 7/0382

(57) ABSTRACT

A photoresist stripper including a quaternary ammonium hydroxide, an alkanolamine compound, and an organic solvent, in which a content of the component is in a range of 45% to 90% by mass, and the component contains a nitrogen-containing heterocyclic aromatic compound.

### BACKGROUND OF THE INVENTION

### Field of the Invention

The present invention relates to a photoresist stripper. In particular, the present invention relates to a photoresist stripper with excellent stripping properties (cleaning properties), which is suitably used in a step of producing a package for a semiconductor device such as an IC or an LSI, and a method of treating a substrate using the same.

Priority is claimed on Taiwan Patent Application No. 111111862 filed in Taiwan on Mar. 29, 2022, the content of which is incorporated herein by reference.

### Description of Related Art

In ICs, LSIs, and the like, with high integration of semiconductor devices and a decrease in the size of chips, wiring circuits are micronized and multilayered, and signal delay due to the resistance (wiring resistance) and the wiring capacity of metal films used in semiconductor devices is considered as a problem. Therefore, copper (Cu), which has a lower resistance than that of aluminum (Al), is used to further decrease in the wiring resistance.

In particular, in a step of producing a package for a semiconductor device, an ultra-small-sized wafer level chip size package (W-CSP) used to collectively package semiconductor devices in a wafer state has been produced to deal with the micronizing and multilayering of devices in recent years.

In the W-CSP production step, for example, a conductive metal film (for example, a copper thin film) is formed on a substrate such as a silicon wafer having a passivation film (insulating film) using a sputtering method, a positive tone photoresist pattern is provided on the copper thin film, and the copper thin film is etched using the pattern as a mask to form a copper rewiring pattern. The insulating film and the rewiring pattern are formed of a single layer or a plurality of layers.

Next, a photosensitive dry film formed from a negative tone photoresist is thermocompression-bonded onto the substrate, selectively exposed, and subjected to a development treatment to form a thick photoresist pattern (photocurable pattern), a copper post (bump) is formed by a plating method in a portion where the photoresist pattern is not formed, and the photoresist pattern is removed by a stripper. Thereafter, the entire surface of the substrate is sealed with a sealing resin such that the copper post is completely covered, and both the upper portion of the sealing resin and the upper portion of the copper post are cut. Further, a conductive terminal (copper terminal) is soldered to the top of the copper post which has been cut and exposed, and the wafer is singulated into a package, thereby producing a package.

In the step of producing a package, since a negative tone photoresist (photocurable pattern) is difficult to remove as compared with a positive tone photoresist pattern and is a thick film because the negative tone photoresist pattern is used to form a copper post (bump), the negative tone photoresist pattern is more difficult to remove and strip. Therefore, such a negative tone photoresist which is a thick film that is difficult to remove is required to have excellent stripping properties. In addition, the negative tone photoresist is also required to prevent damage (low corrosiveness) to a metal (copper).

Further, in the related art, a chemical liquid containing a highly polar solvent such as NMP or DMSO has been used as a photoresist stripper (see, for example, Patent Document 1). However, since NMP is a substance of very high concern (SVHC) under the Registration, Evaluation, Authorization and Restriction of Chemicals (REACH) regulations, it is required to use preferably a photoresist stripper that does not contain NMP and more preferably a photoresist stripper that does not contain NMP and DMSO.

Therefore, as a result of intensive examination on a photoresist stripper that contains various solvents replacing NMP and DMSO, the present inventors finally found a chemical liquid capable of achieving both sufficient cleaning characteristics (cleaning properties for a photoresist) and low corrosiveness to gold (Au), titanium (Ti), a tin-silver (SnAg) alloy, copper (Cu), and the like.

[Patent Document 1] Japanese Unexamined Patent Application, First Publication No. 2008-3399

### SUMMARY OF THE INVENTION

### Technical Problem

The present invention has been made in view of the above-described circumstances, and an object of the present invention is to provide a photoresist stripper that has excellent stripping properties for a thick film negative tone photoresist used in a step of producing a package for a semiconductor device (particularly W-CSP) and an excellent effect of suppressing damage to copper and contains no NMP which increases environmental burdens, and a method of treating a substrate using the same.

### Solution to Problem

In order to solve the above-described problems, the present inventors repeatedly conducted intensive research by focusing on various solvents that replace NMP for a photoresist stripper. As a result, it was found that the above-described problems can be solved by allowing the stripper to contain a specific solvent in a predetermined blending amount, thereby completing the present invention. More specifically, the present invention provides the following [1] to [11].

[1]

A photoresist stripper including:
a quaternary ammonium hydroxide (a);
an alkanolamine compound (b); and
an organic solvent (c),
in which a content of the component (c) is in a range of 45% to 90% by mass, and
the component (c) contains a nitrogen-containing heterocyclic aromatic compound (c-1).

[2]

The photoresist stripper according to [1], in which the component (c) further contains a fatty acid amide (c-2).

[3]

The photoresist stripper according to [1] or [2], in which the component (c) is a single solvent of the component (c-1) or a mixed solvent consisting of the component (c-1) and the component (c-2) at a mass ratio satisfying (c-1)/(c-2)=1.0 or greater.

[4]

The photoresist stripper according to [1] or [2], in which the component (a) is tetramethylammonium hydroxide.

[5]

The photoresist stripper according to [1] or [2], further including: a glycol compound (d).

[6]

The photoresist stripper according to [5], in which the component (d) is propylene glycol.

[7]

The photoresist stripper according to [1] or [2], in which the component (b) is monoethanolamine

[8]

The photoresist stripper according to [1] or [2], further including: an alkylhydroxylamine compound as a component (e).

[9]

The photoresist stripper according to [8], further including: a triazole compound as a component (1).

[10]

The photoresist stripper according to [1] or [2], in which the photoresist stripper is used for stripping a photosensitive dry film formed from a negative tone photoresist.

[11]

A method of treating a substrate, including: forming a photosensitive dry film formed from a negative tone photoresist on a substrate on which a metal layer containing copper is formed; exposing and performing a development treatment on the photosensitive dry film; electrolytically plating the substrate to form a copper post in a portion where a photoresist pattern is not formed; and cleaning and removing a residue of the negative tone photosensitive dry film with the photoresist stripper according to any one of [1] to [10].

### Advantageous Effects of Invention

The photoresist stripper according to the present invention does not contain NMP designated as a substance of very high concern (SVHC) which is a possibly hazardous substance in the REACH regulations and has excellent stripping properties for a thick film negative tone photoresist used in a step of producing W-CSP and an excellent effect of suppressing damage to copper, that is, the photoresist stripper is capable of achieving both sufficient cleaning properties for a photoresist and low corrosiveness to copper (Cu) and the like.

The description above should not be considered to disclose all embodiments of the present invention or all advantages related to the present invention.

### DETAILED DESCRIPTION OF THE INVENTION

Hereinafter, embodiments of the present invention will be described in detail below, but the present invention is not limited to the embodiments described below, and modifications can be made as appropriate within the scope of the object of the present invention.

[Quaternary ammonium hydroxide]

Specific examples of a quaternary ammonium hydroxide as a component (a) include tetramethylammonium hydroxide, tetraethylammonium hydroxide, tetrapropylammonium hydroxide, tetrabutylammonium hydroxide, tetrapentylammonium hydroxide, ethyltrimethylammonium hydroxide, (2-hydroxyethyl)trimethylammonium hydroxide, (2-hydroxyethyl)triethylammonium hydroxide, (2-hydroxyethyl)tripropylammonium hydroxide, and (1-hydroxypropyl)trimethylammonium hydroxide. Among these, from the viewpoints of availability and excellent safety, tetramethylammonium hydroxide, tetraethylammonium hydroxide, tetrapropylammonium hydroxide, tetrabutylammonium hydroxide, and (2-hydroxyethyl)trimethylammonium hydroxide are preferable. Further, from the viewpoints of high solubility in an object to be cleaned and high cleaning performance, tetramethylammonium hydroxide is more preferable. The component (a) can be used alone or in combination of two or more kinds thereof.

The blending amount of the component (a) is preferably in a range of 0.5% to 5% by mass and more preferably in a range of 1% to 3% by mass. The effect of dissolving and removing the photoresist tends to be weakened in a case where the blending amount of the component (a) is extremely small, and dissolution of copper may be promoted in a case where the blending amount thereof is extremely large.

[Alkanolamine Compound]

Specific examples of an alkanolamine compound as a component (b) include triethanolamine, 2-(2-aminoethoxy)ethanol, N,N-dimethylethanolamine, N,N-diethylethanolamine, N,N-dibutylethanolamine, N-methylethanolamine, N-ethylethanolamine, N-butylethanolamine, N-methyldiethanolamine, and triisopropanolamine Alkanolamine such as monoethanolamine, diethanolamine, monoisopropanolamine, or diisopropanolamine may also be used as the alkanolamine Among these, it is particularly preferable to use monoethanolamine from the viewpoint of having higher cleaning properties for a photoresist than that of other alkanolamines The component (b) can be used alone or in combination of two or more kinds thereof. The blending amount of the component (b) is preferably in a range of 10% to 40% by mass and more preferably in a range of 10% to 20% by mass.

[Organic Solvent]

An organic solvent is used as a component (c). Among examples thereof, a nitrogen-containing heterocyclic aromatic compound (c-1) and a fatty acid amide (c-2) are preferably used. The blending amount of the component (c) is preferably in a range of 45% to 90% by mass, more preferably in a range of 55% to 85% by mass, and particularly preferably in a range of 60% to 80% by mass. The stripping properties may be degraded even in a case where the blending amount of the component (c) is extremely small or extremely large.

<Nitrogen-Containing Heterocyclic Aromatic Compound (c-1)>

A nitrogen-containing heterocyclic aromatic compound is used as a component (c-1). Among examples of the compound, a nitrogen-containing five-membered ring compound having two nitrogen atoms in a ring is preferably used.

The nitrogen-containing five-membered ring compound having two nitrogen atoms in a ring is not particularly limited, and examples thereof include known imidazoles, pyrazoles, and derivatives thereof in the related art. Specific examples thereof include imidazole, 2-methylimidazole, 1,2-dimethylimidazole, 1-methylimidazole, 4-methylimidazole, 2-ethylimidazole, 2-ethyl-4-methylimidazole, vinylimidazole, 2-undecylimidazole, 2-heptadecylimidazole, 2-phenyl-4-methylimidazole, 1-benzyl-2-methylimidazole, pyrazole, and aminopyrazole. Among these, 1-methylimidazole is particularly preferable. The component (c-1) can be used alone or in combination of two or more kinds thereof.

<Fatty Acid Amide (c-2)>

A fatty acid amide is used as a component (c-2). Among examples of the fatty acid amide, N,N-dialkyl fatty acid amides are preferably used.

Specific examples of N,N-dialkyl fatty acid amides include N,N-dimethylformamide, N,N-diethylformamide, N,N-dimethylacetamide, N,N-diethylacetamide, N,N-dimethylisobutylamide, N-ethyl, N-methyl-isobutylamide, N,N-diethylisobutylamide, 2-hydroxy-N,N,2-trimethylpropanamide, N-ethyl-2-hydroxy-N,2-dimethylpropanamide, and N,N-diethyl-2-hydroxy-2-methylpropanamide Among these, N,N-diethylformamide is particularly preferable. The component (c-2) can be used alone or in combination of two or more kinds thereof.

The component (c) is a single solvent of the component (c-1) or a mixed solvent consisting of the component (c-1) and the component (c-2) satisfying (c-1)/(c-2)=1.0 or greater (mass ratio), preferably (c-1)/(c-2)=1.5 or greater (mass ratio), and more preferably (c-1)/(c-2)=1.5 or greater and 4.0 or less (mass ratio). Particularly the photoresist stripping properties in a case of using a negative tone photoresist are improved by using the component (c-1) alone or a mixed solvent of the component (c-1) and the component (C-2) at a specific blending amount ratio. In a case where (c-1)/(c-2)=less than 1.0 (mass ratio) is satisfied, the stripping properties of the photoresist are degraded, and photoresist stripping residues may be observed.

[Glycol Compound]

Specific examples of a glycol compound as a component (d) include ethylene glycol, ethylene glycol monomethyl ether, ethylene glycol monoethyl ether, ethylene glycol monobutyl ether, ethylene glycol monomethyl ether acetate, ethylene glycol monoethyl ether acetate, diethylene glycol, diethylene glycol monoalkyl ether (alkyl is lower alkyl having 1 to 6 carbon atoms) such as diethylene glycol monomethyl ether, diethylene glycol monoethyl ether, diethylene glycol monopropyl ether, or diethylene glycol monobutyl ether (=butyl diglycol), and propylene glycol. Among these, from the viewpoints of a high swelling-suppressing ability, a high anticorrosion ability, and low cost, ethylene glycol, propylene glycol, and diethylene glycol monobutyl ether are particularly preferably used. The component can be used alone or in combination of two or more kinds thereof.

The blending amount of the component (d) is preferably in a range of 5% to 30% by mass and more preferably in a range of 5% to 15% by mass. Corrosion to copper tends to occur in a case where the blending amount of the component (d) is extremely small, and performance of dissolving the photoresist is insufficient so that residues of the photoresist tend to be conspicuous in a case where the blending amount thereof is extremely large.

Further, the stripper of the present invention contains the above-described components (a) to (d) in the above-described blending amounts, and thus the stripper can exhibit the effect of the cleaning properties. Further, components (e) and (f) may be blended as anticorrosives to exhibit the effect of low corrosiveness.

[Alkylhydroxylamine Compound]

Specific examples of alkylhydroxylamines as a component (e) include N-methylhydroxylamine, N-ethylhydroxylamine, N,N-dimethylhydroxylamine, N,N-diethylhydroxylamine, N,N-dipropylhydroxylamine, N-ethyl-N-methylhydroxylamine, N-methyl-N-propylhydroxylamine, N-ethyl-N-propylhydroxylamine, and N-t-butylhydroxylamine. Among these, N,N-diethylhydroxylamine is particularly preferable. The component (e) can be used alone or in combination of two or more kinds thereof.

[Triazole Compound]

Specific examples of a triazole compound as a component (f) include compounds having skeletons such as 1,2,3-triazole, 1,2,4-triazole, 3-amino-1,2,4-triazole, 3-mercapto-1,2,4-triazole, 1-hydroxybenzotriazole, 1-hydroxypropylbenzotriazole, 2,3-dicarboxypropylbenzotriazole, 4-hydroxybenzotriazole, 4-carboxyl-benzotriazole, 4-carboxyl-benzotriazole methyl ester, 4-carboxyl-benzotriazole butyl ester, 4-carboxyl-benzotriazole octyl ester, 5-hexylbenzotriazole, [1,2,3-benzotriazolyl-1-methyl][1,2,4-triazolyl-1-methyl][2-ethylhexyl]amine, 1,2,3-benzotriazole, 5-methyl-benzotriazole (also known as tolyl triazole), 5-ethyl-benzotriazole, 5-propyl-benzotriazole, naphthotriazole, and bis[(1-benzotriazolyl)methyl]phosphonic acid. Among these, 1,2,4-triazole, 3-mercapto-1,2,4-triazole, and 1,2,3-benzotriazole are particularly preferable. The component (f) can be used alone or in combination of two or more kinds thereof.

In a case where an anticorrosive is blended into the stripper of the present invention, the blending amount of the anticorrosive is set to preferably 0.01% by mass or greater and 10% by mass or less in the stripper. Further, the blending amount thereof is set to more preferably 0.1% by mass or greater and 5% by mass or less. Excellent anticorrosion performance can be obtained by setting the blending amount of the anticorrosive in the above-described ranges.

The blending amount may be adjusted by further adding water to the photoresist stripper of the present invention as a residue in the blending amount of the components (a) to (f). The blending amount of water is, for example, 0% by mass or greater and 8% by mass or less and preferably 0% by mass or greater and 7% by mass or less. The blending amount of water may be 0% by mass, but the lower limit of water in a case where the stripper contains water is preferably 0.1% by mass or greater.

[Other Components]

Other components such as a surfactant may be added to the stripper of the present embodiment as long as the effects of the present invention are not impaired. The surfactant is not particularly limited, and examples thereof include a nonionic surfactant, an anionic surfactant, a cationic surfactant, and an amphoteric surfactant.

The photoresist stripper of the present invention can be advantageously used for photoresists that can be developed with an alkali aqueous solution, including negative tone and positive tone photoresists. Examples of such photoresists include (i) a positive tone photoresist containing a naphthoquinone diazide compound and a novolak resin, (ii) a positive tone photoresist containing a compound that generates an acid upon exposure, a compound that is decomposed by an acid and increases the solubility in an alkali aqueous solution, and an alkali-soluble resin, (iii) a positive tone photoresist containing a compound that generates an acid upon exposure and an alkali-soluble resin containing a group that is decomposed by an acid and increases the solubility in an alkali aqueous solution, and (iv) a negative tone photoresist containing a compound that generates an acid or a radical upon exposure, a crosslinking agent, and an alkali-soluble resin, but the present invention is not limited thereto.

[Method of Treating Substrate]

In regard to the method of treating a substrate, for example, the photoresist stripper may be used in the following manner in a case of being used in a step of producing a package for a semiconductor device (particularly W-CSP), but the present invention is not limited thereto.

Specifically, a conductive metal thin film is formed by a sputtering method or the like on a substrate such as a silicon wafer having a passivation film (insulating film). Particularly in the step of producing W-CSP, a copper (Cu) thin film is preferable as a conductive metal thin film. Further, in the present invention, copper (Cu) includes not only pure copper but also copper alloys containing copper as a main component.

Next, a positive tone photoresist pattern is provided on the copper thin film, and the copper thin film is etched using the resist pattern as a mask to form a copper rewiring pattern. The insulating film and the rewiring pattern are formed of a single layer or a plurality of layers.

Next, a photosensitive dry film formed from a negative tone photoresist is thermocompression-bonded onto the substrate having the copper rewiring pattern, selectively exposed, and subjected to a development treatment, thereby forming a thick film photoresist pattern (photocurable pattern). Next, a copper post (bump) is formed by a plating method in a portion where the photoresist pattern is not formed, and the photoresist pattern is removed with a stripper. The thickness of the photocurable pattern also depends on the height of the copper post to be formed, but is typically in a range of 20 to 150 μm. The height of the copper post is typically 20 μm or greater.

Subsequently, the photoresist pattern is subjected to a stripping treatment with the photoresist stripper of the present invention. The stripping treatment in a case of using the stripper of the present invention is typically performed by a dip method, a shower method, or the like. The time for the stripping treatment is not particularly limited as long as the time is sufficient for stripping, but is preferably in a range of 60 to 120 minutes from the viewpoint that the negative tone photoresist is difficult to dissolve or strip as compared with the positive tone photoresist and that the thick film photoresist pattern is stripped.

Thereafter, the entire surface of the substrate is sealed with a sealing resin such that the copper post is completely covered, and both the upper portion of the sealing resin and the upper portion of the copper post are cut. Further, a conductive terminal (copper terminal) is soldered to the top of the copper post which has been cut and exposed, and the wafer is singulated into a package, thereby producing a package.

In a case where the photoresist stripper of the present invention is used in the stripping treatment, the photoresist stripping properties are extremely excellent and corrosiveness to copper is also low even in a case where a negative tone photoresist that is not easy to strip and a thick film photoresist pattern that is more difficult to strip is formed to form a copper post (bump) required to have a certain height.

### EXAMPLES

Next, the present invention will be described in more detail with reference to examples, but the present invention is not limited thereto.

[Preparation of Photoresist Stripper]

The following components were mixed at the compositional ratios listed in Table 1, thereby obtaining photoresist strippers of Examples 1 to 11 and Comparative Examples 1 to 7. Abbreviations in the table represent the following compounds.
TMAH: tetramethylammonium hydroxide
MEA: monoethanolamine
1-MI: 1-methylimidazole
DEF: N,N-diethylformamide
PG: propylene glycol
DEHA: N,N-diethylhydroxylamine
124TAZ: 1,2,4-triazole
3-SH-124TAZ: 3-mercapto-1,2,4-triazole
BTA: 1,2,3-benzotriazole

[Stripping Properties of Photoresist]

A photosensitive dry film (“ORDYL P83280”; manufactured by Tokyo Ohka Kogyo Co., Ltd.) formed from a negative tone photoresist was laminated on a wafer having a copper sputtering film on which a copper rewire was formed. The negative tone photosensitive dry film was selectively exposed and developed via a mask pattern to form a photoresist pattern (film thickness of 280 μm).

Next, a copper post (height of 260 μm) was formed by electrolytic plating in a portion where the photoresist pattern was not formed.

The treated substrate was immersed in the photoresist stripper (70° C.) listed in Table 1 for 1 to 2 hours and observed with an optical microscope or a scanning electron microscope (SEM), and the stripping properties of the photoresist were evaluated according to the following evaluation criteria.

(Evaluation)
A: A case where the time until the completion of stripping was shorter than 2 hours was determined as “A”
B: A case where the time until the completion of stripping was 2 hours or longer was determined as “B”

[Metal Corrosiveness (Dip Method)]

A Si wafer on which copper with a thickness of 200 nm was formed by physical vapor deposition (PVD) was subjected to an immersion treatment in the photoresist stripper listed in Table 1 at 70° C. for 30 or 60 minutes, the substrate was cleaned with pure water, and the sheet resistance value was measured. The etching amount (corrosion amount) of copper was acquired from the results, and the corrosiveness of copper was evaluated (defined by the corrosion rate (A/min) to copper). Further, the sheet resistance value was measured using a resistivity measuring device (“VR‥250”; manufactured by Kokusai Electric Semiconductor Service Inc.).

TABLE 1

| | | | | | | | | | | | | Metal |
|---|---|---|---|---|---|---|---|---|---|---|---|---|
| *Compositional | | | | | | | | | | | | corrosiveness |
| ratio is | | | | | | | (f) | | | | Stripping | (defined |
| in units of | (a) | (b) | (c) | | (d) | (e) | 124 | 3-SH- | | Residue | properties of | by corrosion |
| % by mass | TMAH | MEA | 1-MI | DEF | PG | DEHA | TAZ | 124TAZ | BTA | Water | photoresist | rate to copper) |
| Example 1 | 2 | 10 | 76.7 | | 11.3 | | | | | | A (1 hr) | <10 A/min |
| Example 2 | 2 | 20 | 66.7 | | 11.3 | | | | | | A (1 hr) | <10 A/min |
| Example 3 | 2 | 30 | 56.7 | | 11.3 | | | | | | A (2 hr) | <10 A/min |
| Example 4 | 2 | 40 | 46.7 | | 11.3 | | | | | | A (2 hr) | <10 A/min |
| Example 5 | 2 | 10 | 40 | 36.7 | 11.3 | | | | | | A (1.5 hr) | <10 A/min |
| Example 6 | 2 | 10 | 50 | 26.7 | 11.3 | | | | | | A (1 hr) | <10 A/min |
| Example 7 | 2 | 10 | 60 | 16.7 | 11.3 | | | | | | A (1 hr) | <10 A/min |
| Example 8 | 2 | 10 | 50 | 25.5 | 11.3 | 1 | | | | 0.2 | A (1 hr) | <1 A/min |
| Example 9 | 2 | 10 | 50 | 25.4 | 11.3 | 1 | 0.1 | | | 0.2 | A (1 hr) | <1 A/min |
| Example 10 | 2 | 10 | 50 | 25.3 | 11.3 | 1 | 0.1 | 0.1 | | 0.2 | A (2 hr) | <1 A/min |
| Example 11 | 2 | 10 | 50 | 25.3 | 11.3 | 1 | 0.1 | | 0.1 | 0.2 | A (2 hr) | <1 A/min |
| Comparative | 2 | 10 | | 76.7 | 11.3 | | | | | | B (>2 hr) | <10 A/min |
| Example 1 | | | | | | | | | | | | |
| Comparative | 2 | 20 | | 66.7 | 11.3 | | | | | | B (>2 hr) | <10 A/min |
| Example 2 | | | | | | | | | | | | |
| Comparative | 2 | 30 | | 56.7 | 11.3 | | | | | | B (>2 hr) | <10 A/min |
| Example 3 | | | | | | | | | | | | |
| Comparative | 2 | 40 | | 46.7 | 11.3 | | | | | | B (>2 hr) | <10 A/min |
| Example 4 | | | | | | | | | | | | |
| Comparative | 2 | | 86.7 | | 11.3 | | | | | | B (>2 hr) | <10 A/min |
| Example 5 | | | | | | | | | | | | |
| Comparative | 2 | 10 | 10 | 66.7 | 11.3 | | | | | | B (>2 hr) | <10 A/min |
| Example 6 | | | | | | | | | | | | |
| Comparative | 2 | 10 | 30 | 46.7 | 11.3 | | | | | | B (>2 hr) | <10 A/min |
| Example 7 | | | | | | | | | | | | |

As is apparent in the results listed in Table 1, since the photoresist stripper of the present invention is excellent in stripping a thick film negative tone photoresist used in a step of producing a package for a semiconductor device (particularly a step of producing a W-CSP package) and also excellent in anticorrosion properties to copper, the photoresist stripper can be suitably used in the process of treating a substrate.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

What is claimed is:

1. A photoresist stripper comprising:
a quaternary ammonium hydroxide (a);
an alkanolamine compound (b); and
an organic solvent (c),
wherein a content of the organic solvent (c) is in a range of 45% to 90% by mass, and
the component (c) contains a nitrogen-containing heterocyclic aromatic compound (c-1).

2. The photoresist stripper according to claim 1, wherein the component (c) further comrpises a fatty acid amide (c-2).

3. The photoresist stripper according to claim 1, wherein the component (c) is a single solvent of the component (c-1) or a mixed solvent consisting of the component (c-1) and the component (c-2) at a mass ratio satisfying (c-1)/(c-2)=1.0 or greater.

4. The photoresist stripper according to claim 1, wherein the component (a) is tetramethylammonium hydroxide.

5. The photoresist stripper according to claim 1, further comprising: a glycol compound (d).

6. The photoresist stripper according to claim 5, wherein the component (d) is propylene glycol.

7. The photoresist stripper according to claim 1, wherein the component (b) is monoethanolamine

8. The photoresist stripper according to claim 1, further comprising an alkylhydroxylamine compound as a component (e).

9. The photoresist stripper according to claim 8, further comprising a triazole compound as a component (f).

10. The photoresist stripper according to claim 1, wherein the photoresist stripper is used for stripping a photosensitive dry film formed from a negative tone photoresist.

11. A method of treating a substrate, comprising:
forming a photosensitive dry film formed from a negative tone photoresist on a substrate on which a metal layer containing copper is formed;
exposing and performing a development treatment on the photosensitive dry film;
electrolytically plating the substrate to form a copper post in a portion where a photoresist pattern is not formed; and
cleaning and removing a residue of the negative tone photosensitive dry film with the photoresist stripper according to claim 1.
